(19) United States
(12) Patent Application Publication
(10) Pub. No.: US 2024/0096702 A1
(43) Pub. Date: Mar. 21, 2024

(54) SEMICONDUCTOR APPARATUS AND MANUFACTURING METHOD OF SEMICONDUCTOR APPARATUS

(71) Applicants: KABUSHIKI KAISHA TOSHIBA, Tokyo (JP); Toshiba Infrastructure Systems & Solutions Corporation, Kawasaki-shi (JP)

(72) Inventors: Yuta SUGIMOTO, Kawasaki (JP); Kenta KURODA, Tokyo (JP)

(73) Assignees: KABUSHIKI KAISHA TOSHIBA, Tokyo (JP); Toshiba Infrastructure Systems & Solutions Corporation, Kawasaki-shi (JP)

(21) Appl. No.: 18/469,601

(22) Filed: Sep. 19, 2023

(30) Foreign Application Priority Data
Sep. 20, 2022 (JP) 2022-149375

(51) Int. Cl. H01L 21/768; H01L 23/00; H01L 23/48

(52) U.S. Cl. CPC H01L 21/76898; H01L 23/481; H01L 24/32; H01L 2224/32225

(57) ABSTRACT

A manufacturing method of a semiconductor apparatus according to an embodiment includes forming an electrode on a first main surface of a semiconductor substrate made from a compound semiconductor; forming, at a location where the electrode is formed, a via hole that penetrates the first main surface and a second main surface of the semiconductor substrate, wherein a ratio of a thickness of the semiconductor substrate to a maximum value of a width of an opening in the second main surface is greater than 1; forming a rear-side electrode on a second main surface of the semiconductor substrate in such a manner that the rear-side electrode is electrically coupled to the electrode in the via hole; forming an insulating layer arranged at least a layer above the opening; and forming a solder layer in a layer above the rear-side electrode and the insulating layer.

### CROSS-REFERENCE TO RELATED APPLICATION(S)

This application is based upon and claims the benefit of priority from prior Japanese Patent Application No. 2022-149375, filed Sep. 20, 2022, the entire contents of which are incorporated herein by reference.

### FIELD

Embodiments described herein relate generally to a semiconductor apparatus and a manufacturing method of a semiconductor apparatus.

### BACKGROUND

In a semiconductor apparatus in which a semiconductor device, such as a transistor, etc., is formed on a semiconductor substrate, a via hole spanning from the rear surface of the semiconductor substrate toward the semiconductor device may be formed so as to electrically connect a rear-side electrode formed on the rear surface to the semiconductor device.

When the semiconductor apparatus having the above structure is joined to a package substrate by soldering, if solder formed on a rear-side electrode enters inside a via hole, manufacturing yield may be degraded due to deformation of the rear-side electrode or an electrode of a semiconductor device caused by solder leaching or the solder being spit out to the surface of the semiconductor apparatus.

### BRIEF DESCRIPTION OF THE DRAWINGS

FIG. 1 is a schematic cross-sectional view showing a structure example of a semiconductor apparatus according to an embodiment.

FIG. 2 is a diagram for explaining an example of a manufacturing method of a semiconductor apparatus according to a first embodiment.

FIG. 3 is a diagram for explaining an example of a manufacturing method of a semiconductor apparatus according to a second embodiment.

FIG. 4 is a diagram for explaining an example of a manufacturing method of a semiconductor apparatus according to a third embodiment.

### DETAILED DESCRIPTION

A manufacturing method of a semiconductor apparatus according to an embodiment comprises forming an electrode on a first main surface of a semiconductor substrate made from a compound semiconductor; forming, at a location where the electrode is formed, a via hole that penetrates the first main surface and a second main surface of the semiconductor substrate, wherein a ratio of a thickness of the semiconductor substrate to a maximum value of a width of an opening in the second main surface is greater than 1; forming a rear-side electrode on a second main surface of the semiconductor substrate in such a manner that the rear-side electrode is electrically coupled to the electrode in the via hole; forming an insulating layer arranged at least a layer above the opening; and forming a solder layer in a layer above the rear-side electrode and the insulating layer.

Hereinafter, a semiconductor apparatus and a manufacturing method of a semiconductor apparatus according to multiple embodiments are described, with reference to the accompanying drawings.

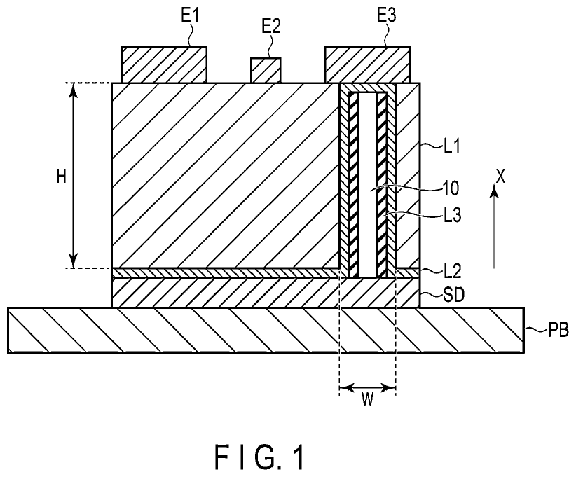

FIG. 1 is a schematic cross-sectional view showing a structure example of a semiconductor apparatus according to the first embodiment.

The semiconductor apparatus of the present embodiment includes a semiconductor device, for example a transistor, and includes a soldering layer SD, a rear-side electrode L2, a semiconductor substrate L1, an insulating layer L3, a first electrode E1, a second electrode E2, and a third electrode E3.

The semiconductor apparatus of the present embodiment is joined to a package substrate PB by the soldering layer SD. In the package substrate PB, a plurality of semiconductor apparatuses are mounted, for example. The package substrate PB is a flat board made of a conductive material, such as copper.

The first electrode E1, the second electrode E2, and the third electrode E3 are arranged on a front surface (first main surface) of the semiconductor substrate L1. The first electrode E1, the second electrode E2, and the third electrode E3 are made of gold (Au), for example. In the present embodiment, the first electrode E1 is for example a drain electrode of the transistor, the second electrode E2 is for example a gate electrode of the transistor, and the third electrode E3 is a source electrode of the transistor.

The semiconductor substrate L1 is a substrate made from a compound semiconductor, which is made of, for example, silicon carbonate (SiC), gallium arsenide (GaAs), and n-type gallium nitride (GaN). The semiconductor substrate L1 may include multiple layers made from a compound semiconductor.

The semiconductor substrate L1 includes a via hole VH formed in such a manner that it extends in a direction substantially parallel to the thickness direction X of the semiconductor substrate L1. The via hole VH penetrates from the back surface side to the front surface side of the semiconductor substrate L1, and a part of the rear face of the third electrode E3 (the surface on the semiconductor substrate L1 side) is exposed through the via hole VH. In other words, the third electrode E3 is arranged on the opening of the via hole VH in the front surface side of the semiconductor substrate L1.

The rear-side electrode L2 is formed between the rear surface (second main surface) of the semiconductor substrate L1 and the solder layer SD. The rear-side electrode L2 is electrically coupled to the third electrode E3 in the via hole VH of the semiconductor substrate L1. The rear-side electrode L2 is made of gold (Au), for example.

The insulating layer L3 is made of a material having a low solder wettability, for example, silicon dioxide (SiO₂) or silicon nitride (SiN). The insulating layer L3 is arranged at a position between the rear-side electrode L2 and the solder layer SD in such a manner that the insulating layer L3 covers the rear-side electrode L2 at the via hole VH of the semiconductor substrate L1.

It is unnecessary for the insulating layer L3 to cover the entirety of the rear-side electrode L2; it suffices that the insulating layer L3 is arranged in such a manner that it covers at least part of the rear-side electrode L2 arranged at the opening of the via hole VH on the rear-surface side and an upper layer in the vicinity thereof. In the example shown in FIG. 1, the insulating layer L3 is arranged on the side surface of the via hole VH extending in a direction substantially parallel to the thickness direction X of the semiconductor substrate L1 in such a manner that the insulating layer L3 covers the rear-side electrode L2.

If the semiconductor apparatus includes the insulating layer L3 arranged in the above-described manner, since it is made of a material having a low solder wettability, the solder arranged on the insulating layer L3 is rejected by the insulating layer L3 and does not flow into the inside of the via hole VH. As a result, the solder layer SD does not enter inside the via hole VH but rather stays in the vicinity of the opening of the via hole VH on the rear surface side.

In the semiconductor apparatus of the present embodiment, solder does not flow into the entire inside of the via hole VH but the opening of the via hole VH on the rear surface side is sealed by the solder layer SD, and a void 10 is thus formed inside the via hole VH. This void 10 is a space surrounded by at least the solder layer SD and the insulating layer L3 in the via hole VH, and in the present embodiment, it is a space surrounded by the solder layer SD, the insulating layer L3, and the rear-side electrode L2.

In the semiconductor apparatus of the present embodiment, the thickness H of the semiconductor substrate L1 with respect to a maximum value of the width W of the opening of the via hole VH (the length in a direction substantially parallel to the second main surface) (the thickness H of the semiconductor substrate L1/the maximum width W of the opening) is greater than 1.

For example, in a case where the opening of the via hole VH is approximately circular, if the aspect ratio of the cross section of the via hole VH in a plane approximately parallel to the thickness direction X of the semiconductor substrate L1 and passing through the center of the opening of the via hole VH (the thickness H of the semiconductor substrate L1/the diameter W of the opening) is equal to or less than 1, in other words, if the thickness H of the semiconductor substrate L1 is equal to or less than the diameter W of the opening, the solder layer SD is likely to enter the inside of the via hole VH even if the insulating layer L3 is provided. This is probably because if the opening of the via hole VH is large and the thickness H of the semiconductor substrate L1 is small, when the semiconductor substrate is joined to the package substrate PB, an amount of solder pressed out toward the inside of the via hole VH increases, and a distance between the rear surface and the front surface of the via hole VH is short, and in turn the solder can easily reach the front surface side of the semiconductor substrate L1.

For this reason, it is desirable that the aspect ratio of the cross section of the via hole VH (the thickness H of the semiconductor substrate L1/the diameter W of the opening) be greater than 1. The opening of the via hole VH is not limited to a circular shape; if the shape of the opening is not a circle, it is desirable that the thickness H of the semiconductor substrate L1 with respect to a maximum value of the width W of the opening of the via hole VH (the thickness H of the semiconductor substrate L1/a maximum width of the opening) be greater than 1.

Next, a manufacturing method of the semiconductor apparatus is described with reference to the drawings.

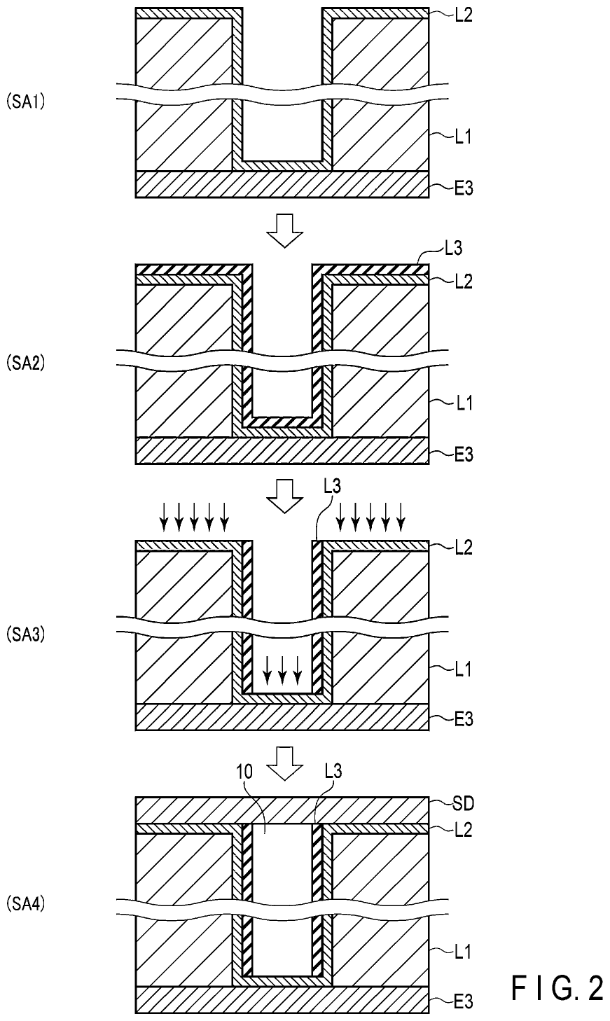

FIG. 2 is an explanatory diagram for explaining an example of a manufacturing method of a semiconductor apparatus according to the first embodiment.

First, a via hole VH is formed on the rear surface side of the semiconductor substrate L1. For example, an etching mask (not shown) is used, and a predetermined part of the semiconductor substrate L1 is selectively removed, and a via hole VH is thereby formed. The etching mask is a silicon oxide film, for example.

The via hole VH is formed via an inductively coupled plasma dry etching method, for example. If the semiconductor substrate L1 is an SiC substrate, for example, the via hole VH can be formed by etching a predetermined part of the SiC substrate using an fluorine-containing etching gas. The via hole VH is formed with a depth that reaches the third electrode E3, penetrating the semiconductor substrate L1.

Subsequently, a rear-side electrode L2 is formed on the rear side of the semiconductor substrate L1 (step SA1). The rear-side electrode L2 is formed by sputtering or plating, for example. The rear-side electrode L2 contains gold, for example.

Next, an insulating film is formed on the rear-side electrode L2 via, for example, a chemical vapor deposition (CVD) method or an atomic layer deposition (ALD) method (step SA2). The insulating film is made of silicon dioxide (SiO₂) or silicon nitride (SiN), for example, and formed in such a manner that it covers the rear-side electrode L2 in the via hole VH.

Subsequently, the insulating film is etched in the thickness direction X of the semiconductor substrate L1 by dry etching, for example responsive ion etching (RIE), so as to form an insulating layer L3 (step SA3). In other words, the insulating film (insulating layer L3) is removed, except for the part formed on the side surface of the via hole VH, by performing anisotropic etching in the thickness direction X of the semiconductor substrate L1.

Subsequently, solder is applied to the rear-face side of the semiconductor apparatus (the rear-side electrode L2 and the insulating layer L3), and a solder layer SD is formed (step SA4). At this time, the solder is rejected by the insulating layer L3, and it is thus possible to prevent the solder from flowing into the via hole VH. As a result, a void 10 surrounded by the solder layer SD, the insulating layer L3, and the rear-side electrode L2 is formed in the via hole VH.

As described above, according to the semiconductor apparatus and the manufacturing method of the semiconductor apparatus according to the present embodiment, it is possible to prevent the solder layer SD from entering the via hole VH and to improve yield in manufacturing the semiconductor apparatus.

Next, a semiconductor apparatus and a manufacturing method of a semiconductor apparatus according to the second embodiment are described in detail, with reference to the accompanying drawings. In the following description, the same components as those in the above-described first embodiment will be assigned with the same reference numerals, and detailed descriptions thereof will be omitted.

The semiconductor apparatus of the present embodiment differs from the foregoing first embodiment in the structure of the insulating layer L3.

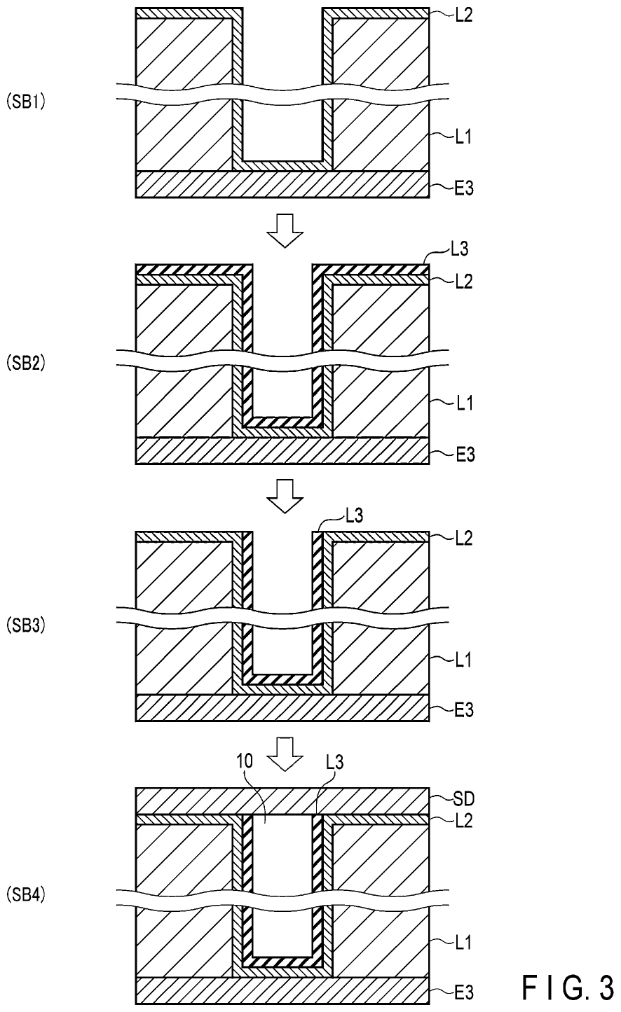

FIG. 3 is an explanatory diagram for explaining an example of a manufacturing method of a semiconductor apparatus according to a second embodiment.

First, similar to the foregoing first embodiment, a via hole VH is formed from the rear-surface side of the semiconductor substrate L1. Subsequently, a rear-side electrode L2 is formed on the rear side of the semiconductor substrate L1 (step SB1). The rear-side electrode L2 is formed by sputtering or plating, for example. The rear-side electrode L2 contains gold, for example.

Next, an insulating film is formed on the rear-side electrode L2 via, for example, a chemical vapor deposition (CVD) method or an atomic layer deposition (ALD) method (step SB2). The insulating film is made of silicon dioxide (SiO₂) or silicon nitride (SiN), for example, and formed in such a manner that it covers the rear-side electrode L2 in the via hole VH.

Subsequently, the insulating film on the rear surface of the semiconductor substrate L1 is polished by a chemical mechanical polishing (CMP) apparatus to form the insulating layer L3 (step SB3). In other words, the insulating film is removed, except for the part formed inside the via hole VH, by the polishing.

Subsequently, solder is applied to the rear-face side of the semiconductor apparatus (the rear-side electrode L2 and the insulating layer L3), and a solder layer SD is formed (step SB4). At this time, the solder is rejected by the insulating layer L3, and it is thus possible to prevent the solder from flowing into the via hole VH. As a result, a void 10 surrounded by the solder layer SD and the insulating layer L3 is formed in the via hole VH.

As described above, according to the semiconductor apparatus and the manufacturing method of the semiconductor apparatus according to the present embodiment, it is possible to prevent the solder layer SD from entering the via hole VH and to improve yield in manufacturing the semiconductor apparatus.

Next, a semiconductor apparatus and a manufacturing method of a semiconductor apparatus according to the third embodiment are described in detail, with reference to the accompanying drawings. In the following description, the same components as those in the above-described first embodiment will be assigned with the same reference numerals, and detailed descriptions thereof will be omitted.

The semiconductor apparatus of the present embodiment differs from the foregoing first embodiment in the structure of the insulating layer L3.

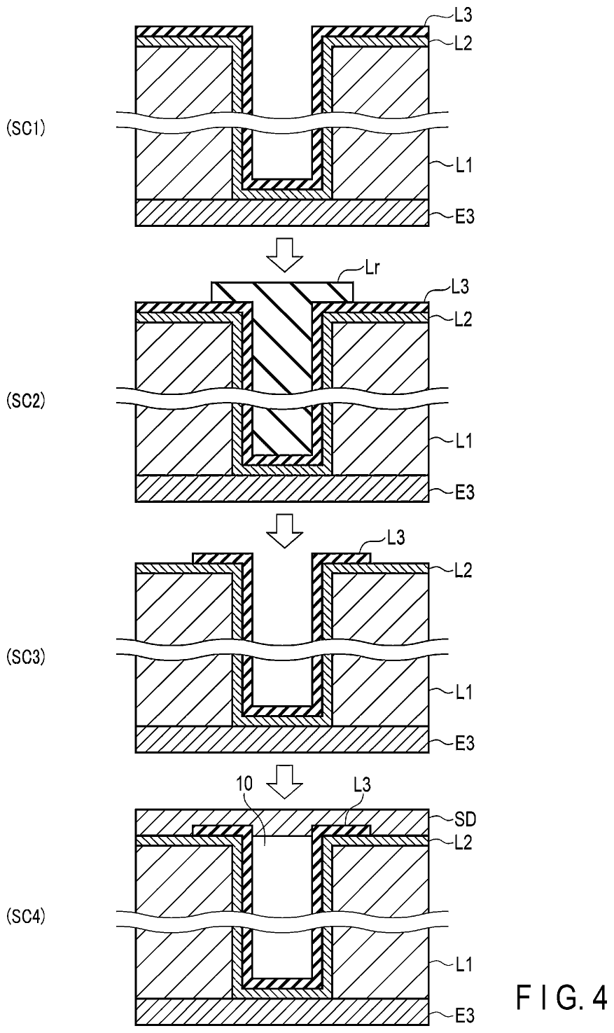

FIG. 4 is an explanatory diagram for explaining an example of a manufacturing method of a semiconductor apparatus according to the third embodiment.

First, similar to the foregoing first embodiment, a via hole VH is formed from the rear-surface side of the semiconductor substrate L1. Subsequently, a rear-side electrode L2 is formed on the rear side of the semiconductor substrate L1. The rear-side electrode L2 is formed by sputtering or plating, for example. The rear-side electrode L2 contains gold, for example.

Next, an insulating film is formed on the rear-side electrode L2 via, for example, a chemical vapor deposition (CVD) method and an atomic layer deposition (ALD) method (step SC1). The insulating film is made of silicon dioxide (SiO₂) or silicon nitride (SiN), for example, and formed in such a manner that it covers the rear-side electrode L2 in the via hole VH.

Subsequently, a photoresist is formed on the insulating film, and the photoresist is exposed via a photo mask and developed, so that a resist pattern Lr is formed on the insulating film in a via hole VH and the peripheral portion thereof (the vicinity of the opening) (step SC2).

Subsequently, the insulating film exposed from the resist pattern Lr is removed via a dry etching method or a wet etching method, and an insulating layer L3 is formed by removing the resist pattern Lr (step SC3). In other words, only the insulating film disposed under the resist pattern Lr (the insulating film formed in the via hole VH and in the vicinity of the opening of the via hole VH) remains and the other parts of the insulating are removed by patterning.

Subsequently, solder is applied to the rear-face side of the semiconductor apparatus (the rear-side electrode L2 and the insulating layer L3), and a solder layer SD is formed (step SC4). At this time, the solder is rejected by the insulating layer L3, and it is thus possible to prevent the solder from flowing into the via hole VH. As a result, a void 10 surrounded by the solder layer SD and the insulating layer L3 is formed in the via hole VH.

As described above, according to the semiconductor apparatus and the manufacturing method of the semiconductor apparatus according to the present embodiment, it is possible to prevent the solder layer SD from entering the via hole VH and to improve yield in manufacturing the semiconductor apparatus.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the invention. The accompanying claims and their equivalents are intended to cover such forms or modifications as would fall within the scope and spirit of the inventions.

What is claimed is:

1. A manufacturing method of a semiconductor apparatus, comprising:
forming an electrode on a first main surface of a semiconductor substrate made from a compound semiconductor;
forming, at a location where the electrode is formed, a via hole that penetrates the first main surface and a second main surface of the semiconductor substrate, wherein a ratio of a thickness of the semiconductor substrate to a maximum value of a width of an opening in the second main surface is greater than 1;
forming a rear-side electrode on a second main surface of the semiconductor substrate in such a manner that the rear-side electrode is electrically coupled to the electrode in the via hole;
forming an insulating layer arranged at least a layer above the opening; and
forming a solder layer in a layer above the rear-side electrode and the insulating layer.

2. The manufacturing method of a semiconductor apparatus according to claim 1, wherein
the forming the insulating layer includes:
forming an insulating film on the rear-side electrode and performing anisotropic etching on the insulating film in a thickness direction of the semiconductor substrate.

3. The manufacturing method of a semiconductor apparatus according to claim 1, wherein
the forming the insulating layer includes:
forming an insulating film on the rear-side electrode and polishing the insulating film arranged on a layer above the second main surface of the semiconductor substrate.

4. The manufacturing method of a semiconductor apparatus according to claim 1, wherein
the forming the insulating layer includes:
forming an insulating film on the rear-side electrode, forming a resist pattern that covers a part of the insulating film formed in the via hole and in the vicinity of the opening, removing the insulating film exposed from the resist pattern by etching, and removing the resist pattern.

5. A semiconductor apparatus further comprising:
a semiconductor substrate having a via hole penetrating a first main surface and a second main surface;
an electrode arranged above a via hole on the first main surface of the semiconductor substrate;
a rear-side electrode arranged on the second main surface of the semiconductor substrate and electrically coupled to the electrode in the via hole; and
an insulating layer arranged on the rear-side electrode in at least part of the via hole, wherein
a ratio of a thickness of the semiconductor substrate to a maximum value of a width of an opening of the via hole is greater than 1.

6. The semiconductor apparatus according to claim 5, further comprising:
a solder layer arranged on the rear-side electrode and the insulating layer; and
a void surrounded at least by the solder layer and the insulating layer in the via hole.
